(19) United States
(12) Patent Application Publication
(10) Pub. No.: US 2004/0199913 A1
(43) Pub. Date: Oct. 7, 2004

(54) Associative memory model for operating system management

(76) Inventor: Michael S. Perrow, Superior, CO (US)

Correspondence Address: HOGAN & HARTSON LLP, ONE TABOR CENTER, SUITE 1500, 1200 SEVENTEEN ST., DENVER, CO, 80202, US

(21) Appl. No.: 10/409,486

(22) Filed: Apr. 7, 2003

(51) Int. Cl. G06F 9/00; H05K 10/00

(52) U.S. Cl. 718/100; 714/25

(57) ABSTRACT

A method of managing an operating system is disclosed. A knowledge base that correlates system parameters with desired stimuli is generated, e.g., by collecting data parameters from the operating system, detecting the presence or absence of a stimula, and correlating the data parameters with the presence or absence of the stimula. The correlation is stored in a suitable memory location associated with the operating system. In subsequent operation system parameters are monitored, and predictions about one or more stimuli are generated based on monitored system parameters.

### BACKGROUND

1. Field of the Invention

The present invention relates to electronic computing systems, and more particularly to operating systems for electronic computing systems.

2. Background

It is known that computing devices incorporate an operating system to manage processing and hardware operations and to function as an interface between higher-level software and hardware. Exemplary operating systems include variants of the UNIX operating system including the Solaris™ operating system commercially available from Sun Microsystems, Inc. of Santa Clara, Calif., USA, and the widely-available Linux operating system, and the Windows® and NT operating system commercially available from Microsoft Corporation of Redmond, Wash., USA.

Operating system management relies primarily on the problem solving skills of system administrators. Frequently, problems with operating systems are not discovered or addressed until a serious error occurs, at which time corrective action may require taking a computer system off-line to address the problem(s). This is an expensive, inconvenient process that may result in a loss of revenue for an enterprise, particularly if the network is running mission-critical applications. Accordingly, there is a need in the art for operating system management tools that can provide advanced warnings of potential operating system problems.

### SUMMARY

In an exemplary embodiment, a method of generating a knowledge base for operating system management is described. The method comprises collecting data parameters from the operating system; detecting the presence or absence of a stimula; correlating the data parameters with the presence or absence of the stimula; and storing the correlation in a suitable memory location associated with the operating system.

In another embodiment, a method of managing an operating system is described. The method comprises generating a knowledge base that correlates system parameters with stimuli; monitoring system parameters during operation of the operating system; and generating a prediction about one or more stimuli based on monitored system parameters. According to a further aspect of this embodiment, generating a knowledge base comprises collecting data parameters from the operating system; detecting the presence or absence of a stimula; correlating the data parameters with the presence or absence of the stimula; and storing the correlation in a suitable memory location associated with the operating system.

In yet another embodiment, a computer readable medium containing program instructions for managing an operating system is described. The computer readable medium comprises computer program code configured to execute the steps of: generating a knowledge base that correlates system parameters with stimuli; monitoring system parameters during operation of the operating system; and generating a prediction about one or more stimuli based on monitored system parameters. According to a further aspect, the program code is further configured to: collect data parameters from the operating system; detect the presence or absence of a stimula; correlate the data parameters with the presence or absence of the stimula; and store the correlation in a suitable memory location associated with the operating system.

### BRIEF DESCRIPTION OF THE DRAWINGS

FIG. 1 is a high-level flowchart illustrating an exemplary method for operating system management;

FIG. 2 is a schematic depiction of an exemplary memory model for use in a system for operating system management;

FIG. 3 is a flowchart illustrating an exemplary method of operating system management; and

FIG. 4 is a schematic illustration of an exemplary computer system in which an associative memory model for operating system management may be implemented.

### DETAILED DESCRIPTION

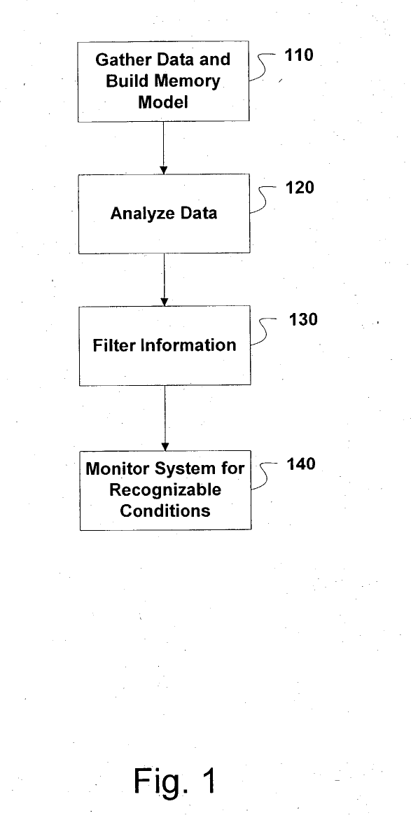

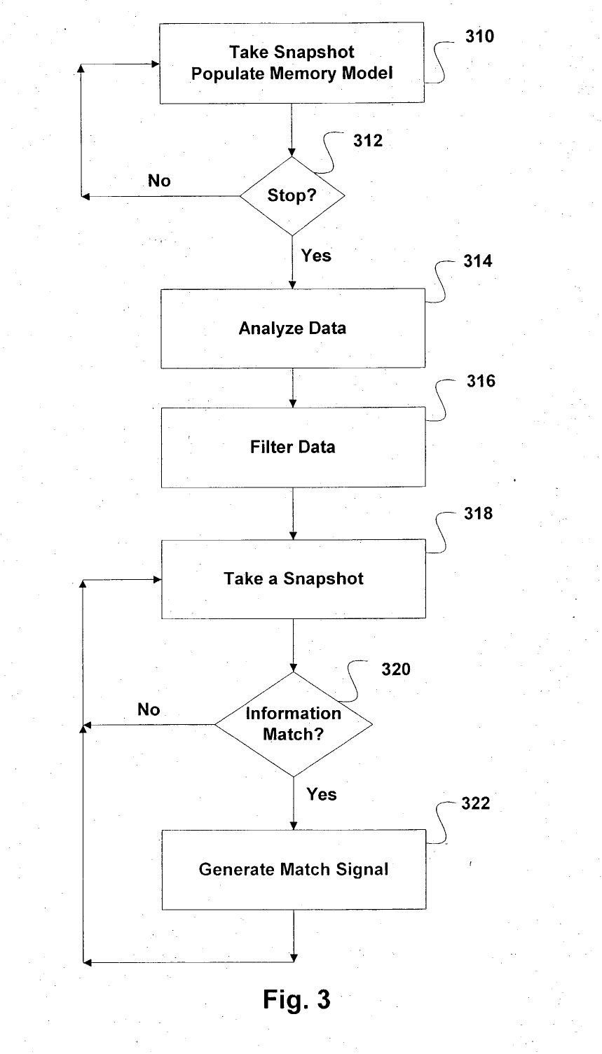

FIGS. 1 and 3 are flowcharts illustrating methods of implementing an associative memory model for managing an operating system. In the following description, it will be understood that each block of the flowchart illustrations, and combinations of blocks in the flowchart illustrations, can be implemented by computer program instructions. These computer program instructions may be loaded onto a computer or other programmable apparatus to produce a machine, such that the instructions which execute on the computer or other programmable apparatus create means for implementing the functions specified in the flowchart block or blocks. These computer program instructions may also be stored in a computer-readable memory that can direct a computer or other programmable apparatus to function in a particular manner, such that the instructions stored in the computer-readable memory produce an article of manufacture including instruction means which implement the function specified in the flowchart block or blocks. The computer program instructions may also be loaded onto a computer or other programmable apparatus to cause a series of operational steps to be performed in the computer or on other programmable apparatus to produce a computer implemented process such that the instructions which execute on the computer or other programmable apparatus provide steps for implementing the functions specified in the flowchart block or blocks.

Accordingly, blocks of the flowchart illustrations support combinations of means for performing the specified functions and combinations of steps for performing the specified functions. It will also be understood that each block of the flowchart illustrations, and combinations of blocks in the flowchart illustrations, can be implemented by special purpose hardware-based computer systems which perform the specified functions or steps, or combinations of special purpose hardware and computer instructions.

FIG. 1 is a high-level flowchart illustrating an exemplary method for operating system management. Referring to FIG. 1, at step 110 data is gathered from the host computer and a data model is constructed. In an exemplary embodiment, data that could be measured may include: available memory, CPU data, disk data, processes and a breakdown of process information, Input/Output (I/O) information, and statistical information about the operating system. The data may be gathered periodically, i.e., by taking snapshots of the data at selected time intervals, or may be measured on a substantially continuous basis. By way of example, in a UNIX operating system the UNIX vmstat command can be used to get information on virtual memory availability and the UNIX df command can be used to get information on available disk space. One of skill in the art of operating systems will understand that other system data may be collected by querying the operating system in a similar fashion.

When data is gathered from the host computer the system monitors the host computer to determine whether any of the stimuli are satisfied. A stimula may include any condition that may be detected by the system. In an exemplary embodiment, stimuli may be assigned as positive or negative. Exemplary positive stimuli may include backups that are conducted at regular intervals, the availability of a minimum amount of disk space and/or memory, CPU availability is above a particular threshold, or whether a root user is logged onto the system. Exemplary negative stimuli may include irregular memory usage, a reduction in the regularity of backups, limited resource availability, and performance drops.

The system may use a simple binary system to assign stimuli as positive or negative. Alternatively, the system may be assigned a scalar positive or negative value. If scalar values are implemented, then the system may compile the scalar values into an overall score indicative of the health of the operating system.

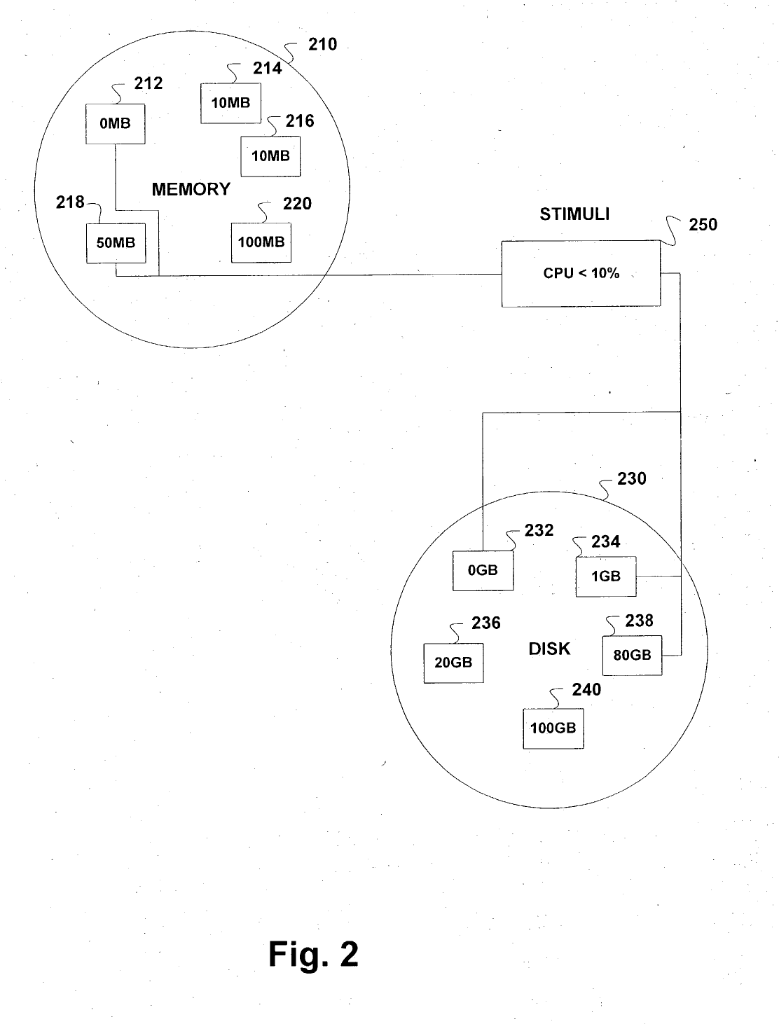

A memory model is also constructed. In an exemplary embodiment, the memory model stores monitored data and correlation(s) between monitored data and stimuli. FIG. 2 is a schematic depiction of an exemplary memory model for use in a system for operating system management. FIG. 2 illustrates a memory model for relating memory available memory and disk space to the stimula of whether the available processor time is below ten percent (10%). The memory model includes three repositories-one for each category of data and one for the stimula. Information collected about the main memory 210 is placed in a first repository 210. Information about the available disk space is placed in a second repository 230. Information about the stimula is placed in the third repository 250.

In operation, the memory model may be populated by taking periodic ‘snapshots’ of operating system parameters. Each time a snapshot is taken, the measurement of available memory is placed in the first repository 210 and the measurement of available disk space is placed in the second repository 230. If the stimula is present, then a link is created between the measurement and the stimula. In an exemplary embodiment, if a link already exists between a measured parameter and the stimula, then the link may be strengthened if a subsequent reading demonstrates another correlation.

By way of example, FIG. 2 illustrates the status of an exemplary memory model after five snapshots have been taken. The memory repository 210 has been populated with five entries including a first entry 212 indicating that at one snapshot the system had 0MB of free memory, second and third entries 214, 216 indicating that at two snapshots the system had 10 MB of free memory, a fourth entry 218 indicating that at one snapshot the system had 50 MB of free memory, and a fifth entry 220 indicating that at one snapshot the system had 100 MB of free memory.

Similarly, the disk space repository 230 has been populated with five entries including a first entry 232 indicating that at one snapshot the disk had 0 GB of free space, a second entry 234 indicating that at one snapshot the disk had 1 GB of free space, a third entry 236 indicating that at one snapshot the disk had 20 GB of free space, a fourth entry 238 indicating that at one snapshot the disk had 80 GB of free space, and a fifth entry 240 indicating that at one snapshot the disk had 100 GB of free space.

A link is established between each entry that is observed when the stimula is present. In the embodiment depicted in FIG. 2, CPU usage was less than ten percent when the snapshots that generated entries 212 and 218 were taken. Therefore, a link is established between each of these entries and the entry for the stimula 250. Similarly, CPU usage was less than ten percent when the snapshots that generated entries 232, 234 and 238 were taken. Therefore, a link is established between each of these entries and the entry for the stimula 250.

Referring back to FIG. 1, after data is gathered and a suitable data model is constructed, the data may be analyzed to discern trends between observed data and stimuli (step 120). The analysis step converts the collected data into useful information that may be used to manage the operating system.

In exemplary embodiments, correlations between the gathered data and stimuli may be determined using known statistical analysis techniques. These techniques may include linear regression techniques, maximum likelihood fitting of multi-variate Gaussian models, mixture models and multi-layer neural networks. At the end of this step, the system may generate rules that describe the data in a general way. This generalization may be used later in a predictive fashion.

Optionally, the system may implement a step 130 to filter the information. In an exemplary embodiment information may be presented to a user to enable a user to manually filter information that the user believes is not useful. In an alternate embodiment, the system may develop intelligence that permits it to filter information that the system believes may not be useful or may be misleading. The information that is retained may be stored in a knowledge base used by the system.

At step 140 the system monitors the operating system for recognizable conditions. During operation of the operation system, the information gathered in the knowledge base is matched against data being gathered from the host computer. The system gathers data from the operating system, and matches it against the knowledge in the knowledge base. Whenever a match is found, the information in the knowledge base is applied to the data to make a prediction about the operating system's behavior.

By way of example, assuming the data collection and analysis process had uncovered a correlation between the available free memory and the negative stimuli of low CPU time available. During operation the system observes that the free memory available is 5 MB. Then the system may generate a prediction that the present operating conditions will result in low CPU time available. This prediction can then be used to either alert a host system administrator, or note in a log, or take some other course of action.

FIG. 3 is a flowchart illustrating an exemplary method of operating system management. In an exemplary embodiment, the system may examine only simple system information such as free memory, and free disk space, and may use simple techniques for analysis of the memory model, such as maximum likelihood modeling with a simple probability distribution (such as the Gaussian distribution). A very simple stimula, e.g., whenever less than 10% of processor time is unused, may be tested.

At step 310, a snapshot is taken, and the memory model is populated. In an exemplary embodiment, the available memory and the available disk space may be read from the host computer's operating system. Also, whether or not the stimula condition is met is determined. This information is used to update the memory model.

The memory model may be implemented in a suitable data storage mechanism, e.g., a database. When a snapshot is taken the memory table is updated. If no row exists in the table for the measured amount of memory, a new row is created with the value of the memory field set to the measured amount of memory and the Stimuli field set to true or false, depending upon whether the condition of the stimuli is satisfied. An exemplary database could be structured comprise one table for each piece of information gathered. For example, the available memory table corresponding to the memory data depicted in FIG. 2 could look like this:

| Memory | Stimuli1 |
|---|---|
| 0 | true |
| 10 | false |
| 10 | false |
| 50 | true |
| 100 | false |

After additional monitoring, the database might look like this:

| Memory | Stimuli1 |
|---|---|
| 0 | true |
| 10 | false |
| 50 | true |
| 100 | false |
| 160 | true |
| 300 | false |
| 340 | true |
| 500 | false |
| 650 | false |

While there is no direct correlation immediately apparent between low memory and low CPU availability, additional sampling and analysis may reveal a statistical correlation between these low memory and low CPU availability.

The same process is then repeated to populate the data models for other parameters and stimuli being monitored by the system. For example, in the data model of FIG. 2 the process would be repeated to populate a memory model correlating disk space and CPU availability.

At step 312 it is determined whether the data-gathering phase should stop. In an exemplary embodiment the system may prompt a user to determine whether the data-gathering phase should be stopped. In another embodiment the system may determine whether sufficient data has been gathered to generate a statistically valid correlation between monitored data and stimuli. If sufficient data has been gathered, then the data collection process may be terminated and control passes to step 314. Alternatively, control passes back to step 310 and another snapshot is taken. In yet another embodiment the data collection process may run indefinitely as a background process. The system may periodically purge all or part of the data in the data models to keep its memory requirements to a manageable level. For example, the system may retain a fixed amount of data in each table, or may place time limits on the duration that data is retained. In other embodiments the system may never stop collecting data. Instead, it may execute as a background process, substantially invisible to a user of the system.

At step 314 the collected data may be analyzed using, e.g., the statistical analysis techniques described above. Step 316 is an optional filtering step as described above.

Steps 318-322 represent the monitoring phase of the process. At step 318 a snapshot of system parameters is taken. At step 320 the data tables are searched to determine whether the sampled data parameters match any data stored in the data tables. If there are matches, then at step 322 a signal is generated indicating that a match occurred. The signal may be used to display a message to the user indicating the prediction represented by the correlation. For example, if a snapshot taken during the monitoring phase reflects that the amount of free memory is low, and the data collected during the analysis phase indicates a strong correlation between low free memory and high CPU utilization, then the system might display a message to the user predicting that CPU utilization may be too high. Alternatively, the signal might be used to implement corrective action. For example, the signal may trigger the operating system to terminate unnecessary processes, or may be stored in a memory location such that when a predetermined number of signals have been generated, corrective action may be implemented.

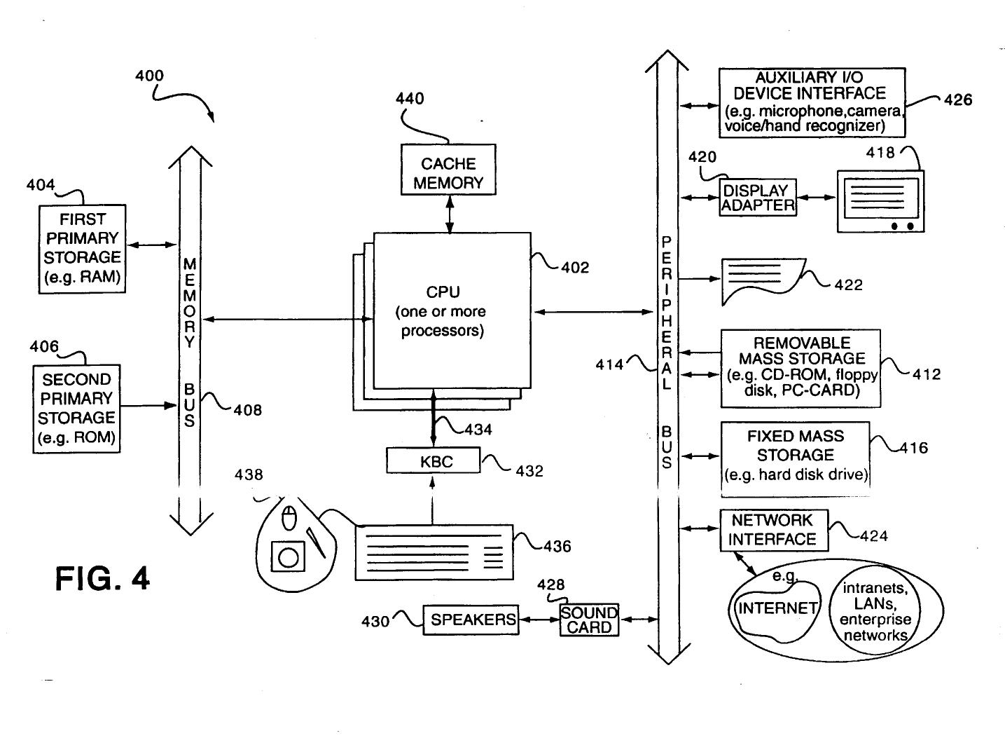

FIG. 4 is a block diagram of a general-purpose computer system 400 suitable for carrying out a method for operating system management as described above. FIG. 4 illustrates one embodiment of a general-purpose computer system. Other computer system architectures and configurations can be used for carrying out the processing of the present invention. Computer system 400, made up of various subsystems described below, includes at least one microprocessor subsystem (also referred to as a central processing unit, or CPU) 402. That is, CPU 402 may be implemented by a single-chip processor or by multiple processors. CPU 402 may be a general-purpose digital processor which controls the operation of the computer system 400. Using instructions retrieved from memory, the CPU 402 controls the reception and manipulation of input data, and the output and display of data on output devices.

CPU 402 may be coupled bi-directionally with a first primary storage 404, typically a random access memory (RAM), and uni-directionally with a second primary storage area 406, typically a read-only memory (ROM), via a memory bus 408. As is well known in the art, primary storage 404 may be used as a general storage area and as scratch-pad memory, and also may be used to store input data and processed data. It also may store programming instructions and data, in the form of threads and processes, for example, in addition to other data and instructions for processes operating on CPU 402, and may be used typically used for fast transfer of data and instructions in a bi-directional manner over the memory bus 408. Also as well known in the art, primary storage 406 typically includes basic operating instructions, program code, data and objects used by the CPU 402 to perform its functions. Primary storage devices 404 and 406 may include any suitable computer-readable storage media, described below, depending on whether, for example, data access needs to be bi-directional or uni-directional. CPU 402 may also directly and very rapidly retrieve and store frequently needed data in a cache memory 430.

A removable mass storage device 412 provides additional data storage capacity for the computer system 400, and is coupled either bi-directionally or uni-directionally to CPU 402 via a peripheral bus 414. For example, a specific removable mass storage device commonly known as a CD-ROM typically passes data uni-directionally to the CPU 402, whereas a floppy disk may pass data bi-directionally to the CPU 402. Storage 412 may also include computer-readable media such as magnetic tape, flash memory, signals embodied on a carrier wave, PC-CARDS, portable mass storage devices, holographic storage devices, and other storage devices. A fixed mass storage 416 also provides additional data storage capacity and may be coupled bi-directionally to CPU 402 via peripheral bus 414. The most common example of mass storage 416 is a hard disk drive. Generally, access to these media is slower than access to primary storages 404 and 406. Mass storage 412 and 416 generally store additional programming instructions, data, and the like that typically are not in active use by the CPU 402. It will be appreciated that the information retained within mass storage 412 and 416 may be incorporated, if needed, in standard fashion as part of primary storage 404 (e.g. RAM) as virtual memory.

In addition to providing CPU 402 access to storage subsystems, the peripheral bus 414 may be used to provide access other subsystems and devices. In an exemplary embodiment, these may include a display monitor 418 and adapter 420, a printer device 422, a network interface 424, an auxiliary input/output device interface 426, a sound card 428 and speakers 430, and other subsystems as needed.

A network interface 424 allows CPU 402 to be coupled to another computer, computer network, or telecommunications network using a network connection. Through network interface 424, it is contemplated that the CPU 402 might receive information, e.g., data objects or program instructions, from another network, or might output information to another network in the course of performing the above-described method steps. Information, often represented as a sequence of instructions to be executed on a CPU, may be received from and outputted to another network, for example, in the form of a computer data signal embodied in a carrier wave. An interface card or similar device and appropriate software implemented by CPU 402 can be used to connect the computer system 400 to an external network and transfer data according to standard protocols. That is, method embodiments of the present invention may execute solely upon CPU 402, or may be performed across a network such as the Internet, intranet networks, or local area networks, in conjunction with a remote CPU that shares a portion of the processing. Additional mass storage devices (not shown) may also be connected to CPU 402 through network interface 424.

Auxiliary I/O device interface 426 represents general and customized interfaces that allow the CPU 402 to send and, more typically, receive data from other devices such as microphones, touch-sensitive displays, transducer card readers, tape readers, voice or handwriting recognizers, biometrics readers, cameras, portable mass storage devices, and other computers.

Also coupled to the CPU 402 is a keyboard controller 432 via a local bus 434 for receiving input from a keyboard 436 or a pointer device 438, and sending decoded symbols from the keyboard 436 or pointer device 438 to the CPU 402. The pointer device may be a mouse, stylus, track ball, or tablet, and is useful for interacting with a graphical user interface.

In addition, embodiments of the present invention further relate to computer storage products with a computer readable medium that contain program code for performing various computer-implemented operations. The computer-readable medium is any data storage device that can store data that can thereafter be read by a computer system. The media and program code may be those specially designed and constructed for the purposes of the present invention, or they may be of the kind well known to those of ordinary skill in the computer software arts. Examples of computer-readable media include, but are not limited to, all the media mentioned above: magnetic media such as hard disks, floppy disks, and magnetic tape; optical media such as CD-ROM disks; magneto-optical media such as floptical disks; and specially configured hardware devices such as application-specific integrated circuits (ASICs), programmable logic devices (PLDs), and ROM and RAM devices. The computer-readable medium can also be distributed as a data signal embodied in a carrier wave over a network of coupled computer systems so that the computer-readable code is stored and executed in a distributed fashion. Examples of program code include both machine code, as produced, for example, by a compiler, or files containing higher level code that may be executed using an interpreter.

It will be appreciated by those skilled in the art that the above described hardware and software elements are of standard design and construction. Other computer systems suitable for use with the invention may include additional or fewer subsystems. In addition, memory bus 408, peripheral bus 414, and local bus 434 are illustrative of any interconnection scheme serving to link the subsystems. For example, a local bus could be used to connect the CPU to fixed mass storage 416 and display adapter 420. The computer system shown in FIG. 4 is but an example of a computer system suitable for use with the invention. Other computer architectures having different configurations of subsystems may also be utilized.

Although the invention has been described and illustrated with a certain degree of particularity, it is understood that the present disclosure has been made only by way of example, and that numerous changes in the combination and arrangement of parts can be resorted to by those skilled in the art without departing from the spirit and scope of the invention, as hereinafter claimed.

The words “comprise,” “comprising,” “include,” “including,” and “includes” when used in this specification and in the following claims are intended to specify the presence of stated features, integers, components, or steps, but they do not preclude the presence or addition of one or more other features, integers, components, steps, or groups.

What is claimed is:

1. A method of generating a knowledge base for operating system management, comprising:
collecting data parameters from the operating system;
detecting the presence or absence of a stimula;
correlating the data parameters with the presence or absence of the stimula; and
storing the correlation in a suitable memory location associated with the operating system.

2. The method of claim 1, wherein collecting data parameters comprises collecting at least one parameter selected from the group of parameters consisting of available memory, CPU utilization, disk utilization, process information, I/O information, and operating system statistics.

3. The method of claim 1, wherein detecting the presence or absence of a stimula comprises detecting a stimula selected from the group of stimuli consisting of CPU utilization, frequency of backup operations, and available disk space.

4. The method of claim 1, further comprising assigning a positive or negative indicia to at least one stimula.

5. The method of claim 1, wherein correlating the data parameters with the presence or absence of the stimula comprises implementing a statistical technique selected from the group of statistical techniques consisting of linear regression, maximum likelihood fitting of multi-variate gaussian models, mixture models and multi-layer neural networks.

6. The method of claim 1, wherein storing the correlation in a suitable memory location associated with the operating system comprises storing correlation information in a database.

7. A method of managing an operating system, comprising:
generating a knowledge base that correlates system parameters with stimuli;
monitoring system parameters during operation of the operating system; and
generating a prediction about one or more stimuli based on monitored system parameters.

8. The method of claim 7, further comprising generating an alert based on the prediction.

9. The method of claim 7, further comprising logging the alert in a memory location.

10. The method of claim 7, wherein generating a knowledge base comprises:
collecting data parameters from the operating system;
detecting the presence or absence of a stimula;
correlating the data parameters with the presence or absence of the stimula; and
storing the correlation in a suitable memory location associated with the operating system.

11. The method of claim 10, wherein collecting data parameters comprises collecting at least one parameter selected from the group of parameters consisting of available memory, CPU utilization, disk utilization, process information, I/O information, and operating system statistics.

12. The method of claim 10, wherein detecting the presence or absence of a stimula comprises detecting a stimula selected from the group of stimuli consisting of CPU utilization, frequency of backup operations, and available disk space.

13. The method of claim 10, further comprising assigning a positive or negative indicia to at least one stimula.

14. The method of claim 10, wherein correlating the data parameters with the presence or absence of the stimula comprises implementing a statistical technique selected from the group of statistical techniques consisting of linear regression, maximum likelihood fitting of multi-variate gaussian models, mixture models and multi-layer neural networks.

15. The method of claim 10, wherein storing the correlation in a suitable memory location associated with the operating system comprises storing correlation information in a database.

16. A computer readable medium containing program instructions for managing an operating system, the computer readable medium comprising computer program code configured to execute the steps of:
generating a knowledge base that correlates system parameters with stimuli; and
monitoring system parameters during operation of the operating system; and
generating a prediction about one or more stimuli based on monitored system parameters.

17. The computer readable medium of claim 16, wherein the program code is further configured to generate an alert based on the prediction.

18. The computer readable medium of claim 16, wherein the program code is further configured to log the alert in a memory location.

19. The computer readable medium of claim 16, wherein the program code is further configured to:
collect data parameters from the operating system;
detect the presence or absence of a stimula;
correlate the data parameters with the presence or absence of the stimula; and
store the correlation in a suitable memory location associated with the operating system.

20. The computer readable medium of claim 19, wherein the program code is further configured to collect at least one parameter selected from the group of parameters consisting of available memory, CPU utilization, disk utilization, process information, I/O information, and operating system statistics.

21. The computer readable medium of claim 19, wherein the program code is further configured to detect the presence or absence of a stimula selected from the group of stimuli consisting of CPU utilization, frequency of backup operations, and available disk space.

22. The computer readable medium of claim 19, wherein the program code is further configured to assign a positive or negative indicia to at least one stimula.

23. The computer readable medium of claim 19, wherein the program code is further configured to correlate the data parameters with the presence or absence of the stimula comprises implementing a statistical technique selected from the group of statistical techniques consisting of linear regression, maximum likelihood fitting of multi-variate gaussian models, mixture models and multi-layer neural networks.

24. The computer readable medium of claim 19, wherein the program code is further configured to store the correlation in a suitable memory location associated with the operating system comprises storing correlation information in a database.
